(19) United States
(12) Patent Application Publication
(10) Pub. No.: US 2026/0180271 A1
(43) Pub. Date: Jun. 25, 2026

(54) ELECTRICAL CONNECTION UNIT

(71) Applicant: Yazaki Corporation, Tokyo (JP)

(72) Inventors: Hiroyuki TANAKA, Kakegawa-shi (JP); Naoki SAKAGUCHI, Kakegawa-shi (JP); Shinya OISHI, Kakegawa-shi (JP)

(73) Assignee: Yazaki Corporation, Tokyo (JP)

(21) Appl. No.: 19/424,915

(22) Filed: Dec. 18, 2025

(30) Foreign Application Priority Data
Dec. 25, 2024 (JP) 2024-228140`

(51) Int. Cl. H01R 25/16; H01R 13/621; H05K 7/20

(52) U.S. Cl. CPC H01R 25/162; H01R 13/6215; H05K 7/2049

(57) ABSTRACT

An electrical connection unit includes: a first electronic component that includes a terminal; a first routing member that includes a first attachment hole and is fixed to the terminal using a fastening member inserted into the first attachment hole; a second routing member that includes a second attachment hole and is fastened together with the first routing member using the fastening member inserted into the second attachment hole; and a heat dissipation portion that is formed integrally with the second routing member.

### BACKGROUND OF THE INVENTION

### Field of the Invention

Embodiments of the present invention relate to an electrical connection unit.

Priority is claimed on Japanese Patent Application No. 2024-228140 filed in Japan on Dec. 25, 2024, the content of which is incorporated herein by reference.

### Description of Related Art

An electrical connection unit including an electronic component (relay), and a routing member (bus bar) and a heat dissipation member, which are fixed to the same terminal of the electronic component using a fastening member, is known. In this type of electrical connection unit, heat of the electronic component is transferred from the terminal to the heat dissipation member, and thus heat dissipation of the electronic component may be promoted.

### [Prior Art Document]

### [Patent Document]

Patent Document 1: Japanese Patent Publication No. 6760203

### SUMMARY OF THE INVENTION

Incidentally, in the electrical connection unit having the heat dissipation member, it is conceivable to fix two routing members to the same terminal of the electronic component. In this case, the number of components fixed to the same terminal increases.

An embodiment provides an electrical connection unit capable of promoting heat dissipation of an electronic component without increasing the number of components fixed to terminals of the electronic component.

According to an embodiment, there is provided an electrical connection unit including: a first electronic component that includes a terminal; a first routing member that includes a first attachment hole and is fixed to the terminal using a fastening member inserted into the first attachment hole; a second routing member that includes a second attachment hole and is fastened together with the first routing member using the fastening member inserted into the second attachment hole; and a heat dissipation portion that is formed integrally with the second routing member.

In the electrical connection unit according to the embodiment, it is possible to promote the heat dissipation of the electronic component without increasing the number of components fixed to the terminals of the electronic component.

### BRIEF DESCRIPTION OF THE DRAWINGS

FIG. 1 is a top view illustrating an electrical connection unit according to an embodiment.

FIG. 2 is a partially exploded perspective view illustrating an electrical connection unit according to the embodiment.

FIG. 3 is an exploded perspective view illustrating a modification example of an electrical connection unit according to the embodiment.

### DETAILED DESCRIPTION OF THE INVENTION

Hereinafter, an embodiment will be described with reference to the drawings. In the following description, constitutions having the same or similar functions are denoted by the same reference numbers. Redundant descriptions of these constitutions may be omitted. The constitutions to be described below do not limit the scope of the embodiment.

In the present disclosure, the terms are defined as follows. The term “connection” is not limited to a mechanical connection, and may include an electrical connection. The term “connection” is not limited to a case where two elements that are connection targets are directly connected, and may include a case where two elements that are connection targets are connected with another element interposed therebetween. The term “facing” or “overlapping” indicates that virtual projection images of two target objects overlap each other when viewed from a specific direction. That is, the term “facing” or “overlapping” is not limited to a case where two target objects directly face each other, and may include a case where two target objects face each other in a state in which another member or a gap exists between the two target objects. “Parallel”, “orthogonal”, or “the same” may include “substantially parallel”, “substantially orthogonal”, or “substantially the same”, respectively.

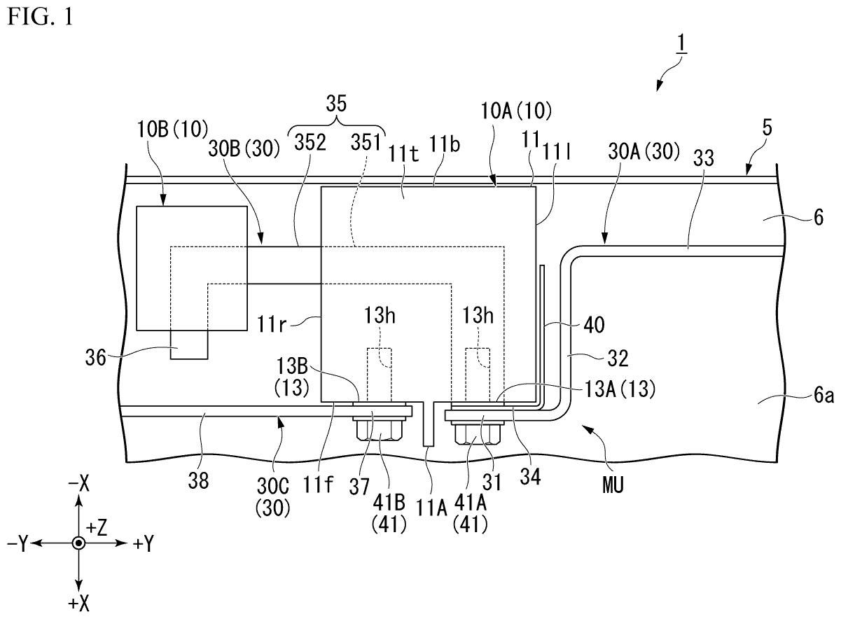

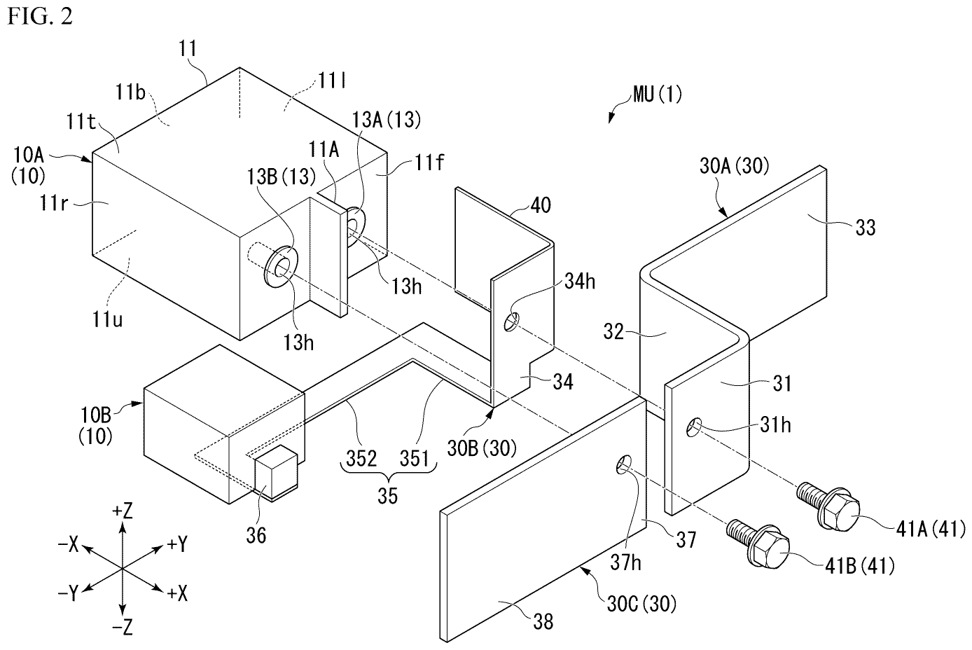

In the present disclosure, a +X direction, a −X direction, a +Y direction, a −Y direction, a +Z direction, and a −Z direction are defined as follows. The +X direction is a direction from a first electronic component 10A to be described later toward connection portions 31 and 37 of first and third bus bars 30A and 30C (see FIG. 1). The −X direction is a direction opposite to the +X direction. In a case where the +X direction and the −X direction are not distinguished from each other, they are simply referred to as “X direction”. The Y direction is a direction intersecting (for example, orthogonal to) the X direction. The +Y direction is a direction from a second terminal 13B of the first electronic component 10A to be described later toward a first terminal 13A (See FIGS. 1 and 2). The −Y direction is a direction opposite to the +Y direction. In a case where the +Y direction and the −Y direction are not distinguished from each other, they are simply referred to as “Y direction”. The +Z direction is a direction intersecting (for example, orthogonal to) the X direction and the Y direction. The +Z direction is a direction from an extension portion 35 of a second bus bar 30B to be described later toward the first electronic component 10A (see FIG. 2). The −Z direction is a direction opposite to the +Z direction. In a case where the +Z direction and the −Z direction are not distinguished from each other, they are simply referred to as “Z direction”.

Hereinafter, in a case where the X direction and the Y direction are not distinguished, they may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation orientation of the electrical connection unit 1).

### 1. Electrical Connection Unit

FIG. 1 is a top view illustrating an electrical connection unit 1 according to an embodiment. FIG. 2 is a partially exploded perspective view illustrating the electrical connection unit 1. The electrical connection unit 1 is, for example, an in-vehicle device mounted on a vehicle such as an electric vehicle (EV), a hybrid electric vehicle (HEV), or a plug-in hybrid electric vehicle (PHEV). For example, the electrical connection unit 1 may be referred to as an “electrical connection box” or a “junction box”. However, the electrical connection unit 1 is not limited to a box-shaped device. The electrical connection unit 1 includes, for example, a housing 5 and a main body MU.

As illustrated in FIG. 1, the housing 5 is a member forming the exterior of the electrical connection unit 1. The housing 5 is made of, for example, a synthetic resin and has an electrical insulating property. The housing 5 accommodates the main body MU. A specific constitution of the housing 5 may be arbitrary. The housing 5 illustrated in FIG. 1 includes an insulating base portion 6 on which the main body MU is placed. The base portion 6 has an upper surface 6a facing the +Z direction side. The main body MU is placed on the upper surface 6a of the base portion 6.

For example, the electrical connection unit 1 may not include the housing 5. For example, the electrical connection unit 1 may have the base portion 6 instead of the housing 5. In the following description, the “housing 5” may be read as the “base portion 6”. Each of the housing 5 and the base portion 6 is an example of a “support” that supports the main body MU.

As illustrated in FIGS. 1 and 2, the main body MU is a portion that performs a main function (for example, switching of electrical connection states or overcurrent protection) of the electrical connection unit 1. The main body MU may be referred to as a “circuit constitution body”. The main body MU includes one or more electronic components 10, a plurality of bus bars 30 (routing members), and a heat dissipation portion 40.

### 2. Electronic Component

First, the electronic components 10 will be described. Each of the electronic components 10 is an electronic component 10 mounted in accordance with a function required for the main body MU. The electronic component 10 according to the present embodiment includes a first electronic component 10A and a second electronic component 10B.

### (First Electronic Component)

The first electronic component 10A may be, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of first electronic component 10A is not limited to the above example. The first electronic component 10A is, for example, a heat generating component that generates heat at the time of energization.

The first electronic component 10A includes, for example, a component body 11, and a plurality of terminals 13.

The component body 11 may have, for example, a functional portion that performs the main function of the first electronic component 10A, and an exterior portion that forms most of the outer shape of the first electronic component 10A. For example, in a case where the first electronic component 10A is a relay, the functional portion of the component body 11 includes a switch (for example, a contact) that switches between a conductive state and a non-conductive state. For example, in a case where the first electronic component 10A is a fuse, the functional portion of the component body 11 includes a fusible portion that melts when an overcurrent flows. For example, in a case where the first electronic component 10A is a capacitor, the functional portion of the component body 11 includes a portion that accumulates electric charge.

The exterior portion of the component body 11 is made of, for example, a synthetic resin and has an electrical insulating property. For example, the functional portion and exterior portion of the component body 11 may be integrally formed.

As illustrated in FIG. 2, the component body 11 of the present embodiment has an insulating rib 11A that protrudes in the horizontal direction (for example, the +X direction) and extends in the Z direction. The insulating rib 11A has, for example, a plate shape formed in the X direction and the Z direction. The insulating rib 11A extends, for example, over the entire length of the component body 11 in the Z direction. The insulating rib 11A is disposed between the adjacent terminals 13 (a first terminal 13A and a second terminal 13B to be described later) when viewed from the X direction. The insulating rib 11A electrically insulates the adjacent terminals 13 from each other. The insulating rib 11A electrically insulates the bus bars 30 (for example, a first bus bar 30A and a third bus bar 30C to be described later) respectively fixed to the two adjacent terminals 13.

As illustrated in FIG. 2, in the present embodiment, the component body 11 constituting the first electronic component 10A is formed in a three-dimensional shape having a plurality of surfaces facing different directions from each other, and corner portions positioned between adjacent surfaces. The number of surfaces of the component body 11 is only required to be two or more. Specifically, the component body 11 is formed in a rectangular parallelepiped shape. The plurality of surfaces of the component body 11 include a front surface 11f facing the +X direction, a rear surface 11b facing the −X direction, an upper surface 11t facing the +Z direction, a lower surface 11u facing the −Z direction, a first side surface 11l facing the +Y direction, and a second side surface 11r facing the −Y direction. The front surface 11f of the component body 11 is an example of a “first surface”, and the lower surface 11u and the first side surface 11l of the component body 11 are examples of a “second surface” adjacent to the first surface. The lower surface 11u of the component body 11 is a surface facing the upper surface 6a (see FIG. 1) of the base portion 6 described above. The insulating rib 11A described above is disposed on the front surface 11f of the component body 11.

Each of the terminals 13 is an electrical connection portion exposed outward from the surface of the component body 11. The terminal 13 is electrically connected to the functional portion of the component body 11 inside the exterior portion of the component body 11. In the present embodiment, the terminal 13 of the electronic component 10 includes a first terminal 13A and a second terminal 13B. One of the first terminal 13A and the second terminal 13B is a terminal on the positive electrode side. The other of the first terminal 13A and the second terminal 13B is a terminal on the negative electrode side.

In the present embodiment, the first terminal 13A and the second terminal 13B are exposed outward from the front surface 11f of the component body 11. The first terminal 13A and the second terminal 13B are arranged in the horizontal direction (for example, the Y direction). Specifically, the first terminal 13A and the second terminal 13B are arranged in order in the −Y direction. The first terminal 13A and the second terminal 13B are not limited to being disposed on the surface of the component body 11 facing the same direction, and may be disposed, for example, on the surface of the component body 11 facing different directions.

Each terminal 13 has an attachment hole 13h into which a fastening member 41 (for example, a screw or a bolt) to be described later is inserted. The attachment hole 13h is open in the horizontal direction (for example, the +X direction). In the present embodiment, the fastening member 41 is inserted into the attachment hole 13h from the X direction (for example, from the +X direction side). The inner circumferential surface of the attachment hole 13h of the electronic component 10 has screw grooves. The attachment hole 13h is a bottomed hole provided in the electronic component 10.

### (Second Electronic Component)

The second electronic component 10B may be, for example, a relay, a register, a conductance detection circuit, or the like. However, the type of second electronic component 10B is not limited to the above example. Since the current flowing through the second electronic component 10B is lower than the current flowing through the first electronic component 10A, the amount of heat generation of the second electronic component 10B at the time of energization is sufficiently lower than the amount of heat generation of the first electronic component 10A.

The second electronic component 10B is electrically connected to the first electronic component 10A via the second bus bar 30B to be described later.

### 3. Bus Bar

As illustrated in FIGS. 1 and 2, each of the plurality of bus bars 30 is a routing member that electrically connects two or more connection targets. The bus bar 30 is made of metal (for example, made of copper, made of a copper alloy, made of aluminum, or made of an aluminum alloy) and has conductivity. The connection target connected to the bus bar 30 may be, for example, the electronic component 10 described above, another electronic component (not illustrated), another bus bar (not illustrated), or the like. A specific example of the another electronic component may be, for example, similar to the first electronic component 10A or the second electronic component 10B described above. The “routing member” in the present disclosure is not limited to the bus bar 30 and the another bus bar, and may be any connection component that electrically connects two or more connection targets.

The bus bar 30 of the present embodiment includes a first bus bar 30A, a second bus bar 30B, and a third bus bar 30C. The first bus bar 30A, the second bus bar 30B, and the third bus bar 30C are examples of a “first routing member”, a “second routing member”, and a “third routing member”, respectively.

### (First Bus Bar)

As illustrated in FIG. 2, the first bus bar 30A has a first attachment hole 31h. The first bus bar 30A is fixed to the first terminal 13A of the first electronic component 10A by a first fastening member 41A (fastening member 41) inserted into the first attachment hole 31h. With such a constitution, the first bus bar 30A is electrically connected to the first electronic component 10A. The first bus bar 30A electrically connects the first electronic component 10A to another electronic component, another bus bar (not illustrated), or the like. The first bus bar 30A of the present embodiment is formed in a plate shape.

The first bus bar 30A includes, for example, a connection portion 31, a first extension portion 32, and a second extension portion 33. In the present embodiment, the entire first bus bar 30A including the connection portion 31, the first extension portion 32, and the second extension portion 33 is formed of one plate member. The connection portion 31, the first extension portion 32, and the second extension portion 33 are each formed in a flat plate shape.

The connection portion 31 of the first bus bar 30A is a portion connected to the first terminal 13A of the first electronic component 10A. The connection portion 31 is a plate portion along the Y direction and the Z direction with the X direction as a thickness direction. The connection portion 31 includes a portion overlapping the first electronic component 10A in the X direction. From another view point, the connection portion 31 includes a portion overlapping the first fastening member 41A inserted into the attachment hole 13h of the first terminal 13A when viewed from the X direction.

The connection portion 31 includes the first attachment hole 31h. The first attachment hole 31h is, for example, a through hole penetrating the connection portion 31 in the X direction. The first attachment hole 31h does not have, for example, screw grooves. The first attachment hole 31h faces the attachment hole 13h of the first electronic component 10A in the X direction. The first fastening member 41A is inserted into the first attachment hole 31h in the X direction. The first fastening member 41A inserted through the first attachment hole 31h is engaged with the attachment hole 13h of the first terminal 13A of the first electronic component 10A. With this constitution, the connection portion 31 of the first bus bar 30A and the first terminal 13A of the first electronic component 10A are physically and electrically connected (see FIG. 1). The connection portion 31 of the first bus bar 30A overlaps the front surface 11f of the first electronic component 10A (see FIG. 1).

The first extension portion 32 extends from an edge of the connection portion 31 when viewed from the X direction. The first extension portion 32 extends along the surface of the first electronic component 10A in a state in which the connection portion 31 of the first bus bar 30A is fixed to the first electronic component 10A. In the present embodiment, the first extension portion 32 is bent in the −X direction from an end portion of the connection portion 31 on the +Y direction side and extends in the −X direction. The first extension portion 32 extends along the first side surface 11l of the first electronic component 10A. The first extension portion 32 is a plate portion along the X direction and the Z direction with the Y direction as a thickness direction. The first extension portion 32, which is such a plate portion, overlaps the first side surface 11l of the first electronic component 10A in a state in which the connection portion 31 of the first bus bar 30A is fixed to the first electronic component 10A (see FIG. 1).

The second extension portion 33 extends from an edge of the first extension portion 32 when viewed from the Y direction. The second extension portion 33 extends in a direction away from the first electronic component 10A in a state in which the connection portion 31 of the first bus bar 30A is fixed to the first electronic component 10A. In the present embodiment, the second extension portion 33 is bent in the +Y direction from an end portion of the first extension portion 32 in the −X direction and extends in the +Y direction. The second extension portion 33 extends in the +Y direction so as to be away from the first side surface 11l of the first electronic component 10A (see FIG. 1). Similarly to the connection portion 31, the second extension portion 33 is a plate portion along the Y direction and the Z direction with the X direction as a thickness direction.

Specific aspects (shapes and components) of the first bus bar 30A are not limited to the above, and may be arbitrary.

### (Second Bus Bar)

As illustrated in FIG. 2, the second bus bar 30B has a second attachment hole 34h. The second bus bar 30B is fastened together with the first bus bar 30A by inserting the first fastening member 41A into the second attachment hole 34h, and is fixed to the first terminal 13A of the first electronic component 10A. With such a constitution, the second bus bar 30B is electrically connected to the first electronic component 10A. The second bus bar 30B electrically connects the first electronic component 10A to the second electronic component 10B. For example, the second bus bar 30B may electrically connect the first electronic component 10A to another electronic component, another bus bar (not illustrated), or the like.

The second bus bar 30B of the present embodiment is formed in a plate shape. The thickness dimension of the second bus bar 30B is smaller than the thickness dimension of the plate-shaped first bus bar 30A. The thickness dimension of the second bus bar 30B may be, for example, half or less of the thickness dimension of the first bus bar 30A. A low-voltage current flows through the second bus bar 30B as compared to the first bus bar 30A.

The second bus bar 30B is bent to overlap both of two surfaces (a first surface and a second surface) adjacent to each other and facing different directions.

The second bus bar 30B includes, for example, a connection portion 34 and an extension portion 35. In the present embodiment, the entire second bus bar 30B including the connection portion 34 and the extension portion 35 is formed of one plate member. The connection portion 34 and the extension portion 35 of the second bus bar 30B are each formed in a flat plate shape. The connection portion 34 of the second bus bar 30B is an example of a “first portion of the second routing member”, and the extension portion 35 of the second bus bar 30B is an example of a “second portion of the second routing member”.

The connection portion 34 of the second bus bar 30B is a portion connected to the first terminal 13A of the first electronic component 10A. The connection portion 34 is a plate portion along the Y direction and the Z direction with the X direction as a thickness direction. The connection portion 34 includes a portion overlapping the first electronic component 10A in the X direction. From another view point, the connection portion 34 includes a portion overlapping the first fastening member 41A inserted into the attachment hole 13h of the first terminal 13A when viewed from the X direction.

In the present embodiment, the connection portion 34 of the second bus bar 30B is sandwiched between the first terminal 13A of the first electronic component 10A and the connection portion 31 of the first bus bar 30A. For example, the connection portion 34 of the second bus bar 30B may be disposed so as to sandwich the connection portion 31 of the first bus bar 30A with the first terminal 13A of the first electronic component 10A.

The connection portion 34 includes the second attachment hole 34h. The second attachment hole 34h is, for example, a through hole penetrating the connection portion 34 in the X direction. The second attachment hole 34h does not have, for example, screw grooves. The second attachment hole 34h faces the attachment hole 13h of the first electronic component 10A and the first attachment hole 31h of the first bus bar 30A in the X direction. The first fastening member 41A is inserted into the second attachment hole 34h in the X direction. When the first fastening member 41A inserted through the first attachment hole 31h and the second attachment hole 34h is engaged with the attachment hole 13h of the first electronic component 10A, the connection portion 34 of the second bus bar 30B is fastened together with the connection portion 31 of the first bus bar 30A, and is fixed to the first terminal 13A of the first electronic component 10A. With such a constitution, the connection portion 34 of the second bus bar 30B and the connection portion 31 of the first bus bar 30A are physically and electrically connected to the first terminal 13A of the first electronic component 10A (see FIG. 1). The connection portion 34 of the second bus bar 30B overlaps the front surface 11f of the first electronic component 10A together with the connection portion 31 of the first bus bar 30A (see FIG. 1).

The extension portion 35 of the second bus bar 30B is a portion that extends from the connection portion 34 and is connected to the second electronic component 10B. The extension portion 35 extends from an edge of the connection portion 34 when viewed from the X direction. The proximal end portion 351 of the extension portion 35 in the extension direction extends along the surface of the first electronic component 10A in a state in which the connection portion 34 of the second bus bar 30B is fixed to the first electronic component 10A. The distal end portion 352 of the extension portion 35 in the extension direction extends in a direction away from the first electronic component 10A.

As illustrated in FIGS. 1 and 2, in the present embodiment, the extension portion 35 is bent in the −X direction from an end portion of the connection portion 34 on the −Z direction side and extends in the −X direction. The extension portion 35 is a plate portion along the X direction and the Y direction with the Z direction as a thickness direction. The proximal end portion 351 of the extension portion 35 extends along the lower surface 11u of the first electronic component 10A. The distal end portion 352 of the extension portion 35 extends in a direction (−Y direction) away from the second side surface 11r of the first electronic component 10A when viewed from the Z direction.

For example, the extension portion 35 is connected to the second electronic component 10B at a distal end portion of the extension portion 35 in the extension direction. Specifically, a terminal portion 36 is provided at a distal end portion of the extension portion 35 in the extension direction, the distal end portion being positioned away from the first electronic component 10A. The second electronic component 10B is connected to the terminal portion 36 of the extension portion 35. In FIGS. 1 and 2, in a state in which the second electronic component 10B is connected to the terminal portion 36 of the extension portion 35, the second electronic component 10B is positioned on the upper side (+Z direction side) of the distal end portion of the extension portion 35. The position of the second electronic component 10B with respect to the distal end portion of the extension portion 35 is not limited to the above example. The connection mode of the second electronic component 10B to the distal end portion of the extension portion 35 is not limited to the above-described mode.

The second electronic component 10B connected to the extension portion 35 in this manner is positioned adjacent to the first electronic component 10A. In FIG. 1, the second electronic component 10B is positioned on the −Y direction side with respect to the first electronic component 10A, but the position of the second electronic component 10B with respect to the first electronic component 10A is not limited to the above example. In FIG. 1, the second electronic component 10B is positioned at a distance from the first electronic component 10A, but may be in contact with, for example, the first electronic component 10A.

Specific aspects (shapes and components) of the second bus bar 30B are not limited to the above, and may be arbitrary.

### (Third Bus Bar)

As illustrated in FIG. 2, the third bus bar 30C has a third attachment hole 37h. The third bus bar 30C is fixed to the second terminal 13B of the first electronic component 10A by a second fastening member 41B (fastening member 41) inserted into the third attachment hole 37h. With such a constitution, the third bus bar 30C is electrically connected to the first electronic component 10A. The third bus bar 30C electrically connects the first electronic component 10A to another electronic component, another bus bar (not illustrated), or the like. The third bus bar 30C of the present embodiment is formed in a plate shape. The thickness dimension of the third bus bar 30C in the present embodiment is the same as the thickness dimension of the first bus bar 30A. The thickness dimension of the third bus bar 30C may be different from the thickness dimension of the first bus bar 30A. A current having a voltage (high voltage) equivalent to that of the first bus bar 30A flows through the third bus bar 30C.

The third bus bar 30C includes, for example, a connection portion 37 and an extension portion 38. In the present embodiment, the entire third bus bar 30C including the connection portion 37 and the extension portion 38 is formed of one plate member. The connection portion 37 and the extension portion 38 of the third bus bar 30C are each formed in a flat plate shape.

The connection portion 37 of the third bus bar 30C is a portion connected to the second terminal 13B of the first electronic component 10A. The connection portion 37 is a plate portion along the Y direction and the Z direction with the X direction as a thickness direction. The connection portion 37 includes a portion overlapping the first electronic component 10A in the X direction. From another view point, the connection portion 37 includes a portion overlapping the second fastening member 41B inserted into the attachment hole 13h of the second terminal 13B when viewed from the X direction.

The connection portion 37 includes the third attachment hole 37h. The third attachment hole 37h is, for example, a through hole penetrating the connection portion 37 in the X direction. The third attachment hole 37h does not have, for example, screw grooves. The third attachment hole 37h faces the attachment hole 13h of the first electronic component 10A in the X direction. The second fastening member 41B is inserted into the third attachment hole 37h in the X direction. The second fastening member 41B inserted through the third attachment hole 37h is engaged with the attachment hole 13h of the second terminal 13B of the first electronic component 10A. With this constitution, the connection portion 37 of the third bus bar 30C and the second terminal 13B of the first electronic component 10A are physically and electrically connected (see FIG. 1). The connection portion 37 of the third bus bar 30C overlaps the front surface 11f of the first electronic component 10A (see FIG. 1).

The extension portion 38 extends from an edge of the connection portion 37 when viewed from the X direction. The extension portion 38 extends in a direction away from the first electronic component 10A in a state in which the connection portion 37 of the third bus bar 30C is fixed to the first electronic component 10A. In the present embodiment, the extension portion 38 extends in the −Y direction from the end portion of the connection portion 37 on the −Y direction-side. The extension portion 38 extends along the first side surface 11l of the first electronic component 10A. The extension portion 38 extends in the −Y direction so as to be away from the second side surface 11r of the first electronic component 10A. Similarly to the connection portion 37, the extension portion 38 is a plate portion along the Y direction and the Z direction with the X direction as a thickness direction. That is, the entire third bus bar 30C including the connection portion 37 and the extension portion 38 is formed in a single flat plate shape.

Specific aspects (shapes and components) of the third bus bar 30C are not limited to the above, and may be arbitrary.

### 4. Heat Dissipation Portion

The heat dissipation portion 40 dissipates heat from the first electronic component 10A. As illustrated in FIG. 2, the heat dissipation portion 40 is formed integrally with the second bus bar 30B. Specifically, the heat dissipation portion 40 is formed of one plate member together with the second bus bar 30B. That is, the heat dissipation portion 40 is formed in a plate shape. In the present embodiment, the heat dissipation portion 40 is formed integrally with the connection portion 34 of the second bus bar 30B.

The thickness dimension of the heat dissipation portion 40 formed integrally with the second bus bar 30B is the same as the thickness dimension of the second bus bar 30B and smaller than the thickness dimension of the first bus bar 30A.

The heat dissipation portion 40 overlaps the surface of the first electronic component 10A. By bending the plate member constituting the second bus bar 30B and the heat dissipation portion 40, the second bus bar 30B and the heat dissipation portion 40, which are plate-shaped, overlap the two surfaces of the first electronic component 10A where the second bus bar 30B and the heat dissipation portion 40 are adjacent to each other and face in different directions. Specifically, the connection portion 34 of the second bus bar 30B overlaps the front surface 11f of the first electronic component 10A, and the heat dissipation portion 40 continuous with the connection portion 34 of the second bus bar 30B overlaps the first side surface 11l of the first electronic component 10A adjacent to the front surface 11f (see FIG. 1). In other words, the heat dissipation portion 40 extends along the first side surface 11l of the first electronic component 10A. In FIG. 1, the heat dissipation portion 40 is positioned at a distance from the first side surface 11l of the first electronic component 10A in the X direction, but may be in contact with, for example, the first side surface 11l.

As illustrated in FIG. 1, the heat dissipation portion 40 overlapping the first side surface 11l of the first electronic component 10A is positioned between the first side surface 11l of the first electronic component 10A and the first extension portion 32 of the first bus bar 30A in the X direction. The heat dissipation portion 40 and the first extension portion 32 extend along the first side surface 11l of the first electronic component 10A. With the heat dissipation portion 40 and the first extension portion 32 provided in this manner, the first extension portion 32 of the first bus bar 30A extends along the heat dissipation portion 40. In FIG. 1, the first extension portion 32 is parallel to the heat dissipation portion 40, but may be inclined with respect to, for example, the heat dissipation portion 40.

The first extension portion 32 is spaced apart from the heat dissipation portion 40 in the X direction. In FIG. 1, the distance between the first side surface 11l of the first electronic component 10A and the heat dissipation portion 40 is shorter than the distance between the heat dissipation portion 40 and the first extension portion 32.

In the electrical connection unit 1 of the present embodiment configured as described above, a high voltage (for example, 48 V or more) current flows through the first electronic component 10A and the first and third bus bars 30A and 30C. The first electronic component 10A and the first and third bus bars 30A and 30C constitute a high voltage circuit through which a high voltage current flows. On the other hand, a low-voltage (for example, less than 48 V) current flows through the second electronic component 10B and the second bus bar 30B. The second electronic component 10B and the second bus bar 30B constitute a circuit (low voltage circuit) that branches from the high voltage circuit including the first electronic component 10A and the first bus bar 30A with a low voltage current.

### 5. Advantages

As described above, in the electrical connection unit 1 of the present embodiment, since the heat dissipation portion 40 is formed integrally with the second bus bar 30B (second routing member), it is possible to promote the heat dissipation of the first electronic component 10A without increasing the number of components fixed to the same terminal 13 (first terminal 13A) of the first electronic component 10A using the fastening member 41 (first fastening member 41A). Heat of the first electronic component 10A is transferred from the terminal 13 (first terminal 13A) to the heat dissipation portion 40 via the second bus bar 30B, and thus the heat dissipation of the first electronic component 10A is promoted.

In the present embodiment, the heat dissipation portion 40 is formed integrally with the connection portion 34 (first portion) of the second bus bar 30B, which is positioned closer to the terminal 13 (first terminal 13A) than the extension portion 35 (second portion). With such a constitution, as compared with a case where the heat dissipation portion 40 is formed integrally with the extension portion 35, the heat dissipation of the first electronic component 10A through the heat dissipation portion 40 can be efficiently performed.

In the present embodiment, since the heat dissipation portion 40 formed in a plate shape overlaps the surface (first side surface 11l) of the first electronic component 10A, the volume of the portion including the first electronic component 10A and the heat dissipation portion 40 in the electrical connection unit 1 can be suppressed to be small. With such a constitution, the electrical connection unit 1 can be downsized.

In the present embodiment, the first bus bar 30A includes the first extension portion 32 extending along the heat dissipation portion 40, and the first extension portion 32 is positioned at a distance from the heat dissipation portion 40. With such a constitution, heat can be efficiently dissipated from the heat dissipation portion 40 into the air as compared with a case where the first extension portion 32 is positioned without a space from the heat dissipation portion 40. Therefore, the heat dissipation property of the first electronic component 10A can be improved.

In the present embodiment, the first bus bar 30A and the second bus bar 30B are formed in a plate shape, and the thickness dimension of the plate member constituting the second bus bar 30B and the heat dissipation portion 40 is smaller than the thickness dimension of the first bus bar 30A. With such a configuration, it is possible to reduce the axial force loss of the fastening member 41 (first fastening member 41A) for fastening the first bus bar 30A and the second bus bar 30B as compared with a case where the thickness dimension of the plate member constituting the second bus bar 30B and the heat dissipation portion 40 is the same as the thickness dimension of the first bus bar 30A (a case where the thickness dimension of the second bus bar 30B is large).

In the present embodiment, the first electronic component 10A has the front surface 11f (first surface) and the first side surface 11l (second surface), which are adjacent to each other and face in different directions, and the corner portion positioned between the front surface 11f and the first side surface 11l. The thickness dimension of the plate member constituting the second bus bar 30B and the heat dissipation portion 40 is smaller than the thickness dimension of the first bus bar 30A formed in a plate shape. By bending the plate member constituting the second bus bar 30B and the heat dissipation portion 40, the second bus bar 30B (connection portion 34) overlaps the front surface 11f of the first electronic component 10A, and the heat dissipation portion 40 overlaps the first side surface 11l of the first electronic component 10A.

Since the thickness dimension of the plate member constituting the second bus bar 30B and the heat dissipation portion 40 is smaller than the thickness dimension of the first bus bar 30A, the curvature radius of the bent portion when the plate member constituting the second bus bar 30B and the heat dissipation portion 40 is bent can be reduced. With such a constitution, the bent portion of the plate member constituting the second bus bar 30B and the heat dissipation portion 40 can be disposed closer to the corner portion of the first electronic component 10A. The second bus bar 30B (connection portion 34) can be disposed close to the front surface 11f of the first electronic component 10A, and the heat dissipation portion 40 can be disposed close to the first side surface 11l of the first electronic component 10A. As a result, the volume of the portion including the first electronic component 10A, the second bus bar 30B, and the heat dissipation portion 40 in the electrical connection unit 1 can be reduced. Therefore, the electrical connection unit 1 can be downsized.

In the present embodiment, the first electronic component 10A has the front surface 11f (first surface) and the lower surface 11u (second surface), which are adjacent to each other and face in different directions, and the corner portion positioned between the front surface 11f and the lower surface 11u. The thickness dimension of the second bus bar 30B formed in a plate shape is smaller than the thickness dimension of the first bus bar 30A formed in a plate shape. By bending the second bus bar 30B, the second bus bar 30B overlaps both the front surface 11f and the lower surface 11u of the first electronic component 10A. Specifically, the connection portion 34 (first portion) of the second bus bar 30B overlaps the front surface 11f of the first electronic component 10A, and the extension portion 35 (second portion) of the second bus bar 30B overlaps the lower surface 11u of the first electronic component 10A.

Since the thickness dimension of the second bus bar 30B is smaller than the thickness dimension of the first bus bar 30A, the curvature radius of the bent portion when the second bus bar 30B is bent can be reduced. With such a constitution, the bent portion of the second bus bar 30B can be disposed closer to the corner portion of the first electronic component 10A. The second bus bar 30B can be disposed close to both the front surface 11f and the lower surface 11u of the first electronic component 10A. As a result, the volume of the portion including the first electronic component 10A and the second bus bar 30B in the electrical connection unit 1 can be reduced. Therefore, the electrical connection unit 1 can be downsized.

In the present embodiment, the connection portion 34 (first portion) of the second bus bar 30B is positioned between the front surface 11f (first surface) of the first electronic component 10A and the first bus bar 30A (connection portion 31). That is, the connection portion 34 (first portion) of the second bus bar 30B is positioned closer to the front surface 11f (first surface) of the first electronic component 10A than the first bus bar 30A.

With such a constitution, the extension portion 35 (second portion) bent with respect to the connection portion 34 of the second bus bar 30B can be disposed closer to the lower surface 11u (second surface) of the first electronic component 10A. The heat dissipation portion 40 bent with respect to the connection portion 34 of the second bus bar 30B can be disposed closer to the first side surface 11l (second surface) of the first electronic component 10A. Therefore, the electrical connection unit 1 can be further downsized.

### 6. Modification Example

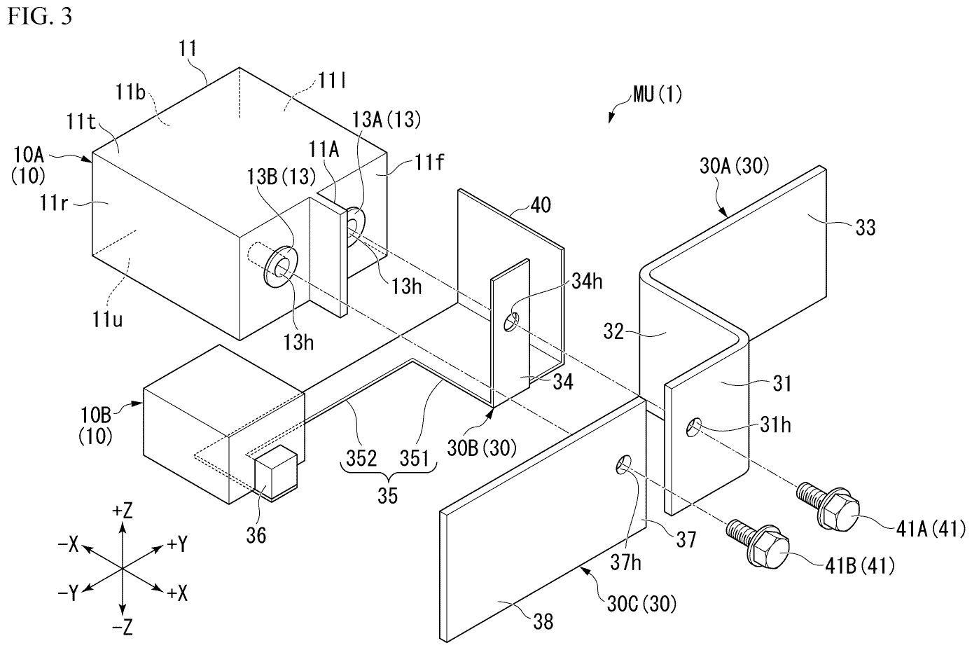

In the above-described embodiment, for example, as illustrated in FIG. 3, the heat dissipation portion 40 may be formed integrally with the extension portion 35 (second portion) of the second bus bar 30B. In the constitution illustrated in FIG. 3, the heat dissipation portion 40 is formed integrally with the proximal end portion 351 of the extension portion 35 of the second bus bar 30B overlapping the lower surface 11u of the first electronic component 10A. In the constitution illustrated in FIG. 3, similarly to the above-described embodiment, the heat dissipation portion 40 overlaps the first side surface 11l of the first electronic component 10A adjacent to the lower surface 11u. Even with such a constitution, the same effects as those of the above-described embodiment are obtained.

In the above-described embodiment, the first electronic component 10A may have, for example, a curved surface. The heat dissipation portion 40, the first bus bar 30A, and the second bus bar 30B may overlap the curved surface of the first electronic component 10A. The portions of the heat dissipation portion 40, the first bus bar 30A, and the second bus bar 30B overlapping the curved surface of the first electronic component 10A may be formed in, for example, a shape along the curved surface (that is, a curved shape).

The embodiment and the modification example have been described above. However, the embodiment and the modification example are not limited to the examples described above. For example, the embodiment and the modification example may be implemented in combination with each other.

### REFERENCE SIGNS LIST

1 Electrical connection unit
10 Electronic component
10A First electronic component
10B Second electronic component
11f Front surface (first surface)
11l First side surface (second surface)
11u Lower surface (second surface)
13 Terminal
13A First terminal
30A First bus bar (first routing member)
30B Second bus bar (second routing member)
31h First attachment hole
32 First extension portion
34 Connection portion (first portion)
34h Second attachment hole
35 Extension portion (second portion)
40 Heat dissipation portion
41 Fastening member

What is claimed is:

1. An electrical connection unit comprising:
a first electronic component that includes a terminal;
a first routing member that includes a first attachment hole and is fixed to the terminal using a fastening member inserted into the first attachment hole;
a second routing member that includes a second attachment hole and is fastened together with the first routing member using the fastening member inserted into the second attachment hole; and
a heat dissipation portion that is formed integrally with the second routing member.

2. The electrical connection unit according to claim 1, further comprising a second electronic component that is electrically connected to the first electronic component,
wherein the second routing member includes a first portion having the second attachment hole and a second portion extending from the first portion and connected to:
the second electronic component; and
the heat dissipation portion is formed integrally with the first portion.

3. The electrical connection unit according to claim 1,
wherein the heat dissipation portion is formed in a plate shape and overlaps a surface of the first electronic component.

4. The electrical connection unit according to claim 3,
wherein the first routing member includes a first extension portion extending along the heat dissipation portion, and
the first extension portion is positioned at a distance from the heat dissipation portion.

5. The electrical connection unit according to claim 1,
wherein the first electronic component includes a first surface and a second surface, which are adjacent to each other and face in different directions, and a corner portion positioned between the first surface and the second surface,
the first routing member is formed in a plate shape,
the second routing member and the heat dissipation portion are formed of one plate member having a smaller thickness dimension than that of the first routing member, and
the second routing member overlaps the first surface and the heat dissipation portion overlaps the second surface by bending the plate member.
